(19) United States
(12) Patent Application Publication
(10) Pub. No.: US 2024/0355583 A1
(43) Pub. Date: Oct. 24, 2024

(54) PLASMA PROCESSING APPARATUS

(71) Applicant: Samsung Electronics Co., Ltd., Suwon-si (KR)

(72) Inventors: Naohiko OKUNISHI, Suwon-si (KR); Hyeong Mo KANG, Suwon-si (KR); Nam Kyun KIM, Suwon-si (KR); Seong Sik NAM, Suwon-si (KR); Seung Bo SHIM, Suwon-si (KR)

(73) Assignee: Samsung Electronics Co., Ltd., Suwon-si (KR)

(21) Appl. No.: 18/431,163

(22) Filed: Feb. 2, 2024

(30) Foreign Application Priority Data
Apr. 21, 2023 (KR) 10-2023-0052664

(51) Int. Cl. H01J 37/32; C23C 16/455; C23C 16/458; C23C 16/509; C23C 16/52

(52) U.S. Cl. CPC H01J 37/32137; C23C 16/45565; C23C 16/4583; C23C 16/509; C23C 16/52; H01J 37/32183; H01J 37/32541

(57) ABSTRACT

A plasma processing apparatus comprises a shower head configured to receive an electrode therein, and a variable impedance controller on the shower head. The variable impedance controller includes a first member spaced apart from the shower head and arranged along a circumference of the shower head, and a second member on the first member and configured to rotate. The variable impedance controller is configured to control an impedance by changing the impedance resulting from the first member and the second member as at least one contact point between the first member and the second member is changed according to rotation of the second member.

### CROSS-REFERENCE TO RELATED APPLICATION

This application claims priority from Korean Patent Application No. 10-2023-0052664 filed on Apr. 21, 2023 in the Korean Intellectual Property Office, and all the benefits accruing therefrom under 35 U.S.C. 119, the contents of which in its entirety are herein incorporated by reference.

### BACKGROUND

Various example embodiments relate to a plasma processing apparatus.

Plasma is widely used in a semiconductor device manufacturing process such as an etching process and/or thin film deposition process and/or an ashing process. The etching process is a process of removing a selected area of a film formed on a substrate and may be carried out in a wet etching or dry etching manner. An etching apparatus using plasma may be used for dry etching.

In order to generate the plasma, an electric field is generated in an inner space of the process chamber so as to excite a process gas contained in the process chamber to a plasma state. In particular, there is a tendency to supply power for the plasma generation using a high-output high-frequency to generate sufficient plasma density in the etching apparatus. For example, RF (Radio Frequency) capacitively-coupled plasma (CCP) and/or inductively-coupled plasma (ICP) source in a form of an electromagnetic wave with a predetermined or dynamically determined frequency and intensity is used as a plasma source.

When using the high-output high frequency RF as the plasma source, harmonic components may be generated in addition to a unique frequency signal involved in the generation of the plasma. It has been identified based on process evaluation data that the harmonic components affect the uniformity of the plasma in a chamber, and as a result, may have a significant impact on performance and results of the process using the plasma. Accordingly, research is being conducted on schemes of removing the harmonic components generated inside the process chamber or appropriately controlling the harmonic components to improve the performance of the process using the plasma.

### SUMMARY

Various example embodiments may provide a plasma processing apparatus capable of efficiently or more efficiently controlling a harmonics signal generated in the chamber.

Purposes and/or features according to various example embodiments are not limited to the above-mentioned features. Other purposes and/or advantages according to various example embodiments that are not mentioned may be understood based on following descriptions, and/or may be more clearly understood according to various example embodiments. Further, it may be easily understood that the purposes and/or advantages according to various example embodiments may be realized using various approaches shown in the claims and combinations thereof.

According to various example embodiments, there is provided a plasma processing apparatus comprising a shower head configured to receive an electrode therein, and a variable impedance controller on the shower head. The variable impedance controller includes a first member spaced apart from the shower head and arranged along a circumference of the shower head, and a second member on the first member and configured to rotate. The variable impedance controller is configured to control an impedance by changing the impedance resulting from the first member and the second member as at least one contact point between the first member and the second member is changed according to rotation of the second member. Alternatively or additionally according to various example embodiments, there is provided a plasma processing apparatus comprising a shower head configured to receive an electrode therein, and a variable impedance controller around the shower head and on the shower head. The variable impedance controller includes, a first member including a first body spaced apart from the shower head and surrounding the shower head, and a plurality of first electrodes branching from the first body and spaced apart from each other, wherein each of the plurality of first electrodes extends toward a center of the first body. The variable impedance controller further includes a second member including, a second body on the shower head, and a plurality of second electrodes branching from the second body and spaced apart from each other, wherein each of the plurality of second electrodes extends toward the first body of the first member. The second member is on the first member and is configured to rotate on the first member.

Alternatively or additionally according to various example embodiments, there is provided a plasma processing apparatus comprising a chamber including a first area configured to have a shower head that is configured to have an upper electrode arranged therein and a lower electrode arranged opposite to the upper electrode, a substrate support module in the chamber and configured to support a substrate thereupon, a gas supply module configured to supply a process gas into the chamber, a power supply module configured to generate a first radio frequency (RF) signal having a first frequency and apply the first RF signal to the lower electrode, a variable impedance controller on the chamber and configured to control an impedance of harmonics generated in the chamber. The variable impedance controller includes, a first member spaced apart from the shower head and arranged along an outer edge of the shower head, and a second member on the first member and configured to rotate. As the second member rotates, at least one contact point between the first member and the second member is changed, such that an impedance resulting from the first member and the second member is changed.

It should be noted that the effects of various example embodiments are not limited to those described above, and other effects of various example embodiments will be apparent from the following description.

### BRIEF DESCRIPTION OF DRAWINGS

The above and other aspects and features of various example embodiments will become more apparent by describing in detail illustrative example embodiments thereof with reference to the attached drawings, in which:

FIG. 1 is a diagram for illustrating a standing wave generated inside a chamber due to harmonics.

FIG. 2 is an illustrative diagram for illustrating a plasma processing apparatus according to some example embodiments.

FIG. 3 is an illustrative diagram for illustrating a plasma processing apparatus according to some further example embodiments.

FIG. 4 is an illustrative diagram for illustrating the variable impedance controller of the plasma processing apparatus as shown in FIG. 3.

FIG. 5 is an illustrative top view of the variable impedance controller as shown in FIG. 4.

FIG. 6 is an illustrative diagram showing a first member of the variable impedance controller in FIG. 5 in a separated state.

FIG. 7 is an illustrative diagram showing a second member of the variable impedance controller in FIG. 5 in a separated state.

FIG. 8 to FIG. 10 are illustrative diagrams for illustrating how the impedance is changed using the variable impedance controller in FIG. 4.

FIG. 11 is an illustrative diagram for illustrating substrate processing or treatment using the plasma processing apparatus of FIG. 3.

FIG. 12 is an illustrative diagram for illustrating a plasma processing apparatus according to some further example embodiments.

FIG. 13 is an illustrative diagram for illustrating a density of plasma generated in a chamber in the plasma processing apparatus of FIG. 12.

FIG. 14 is an illustrative diagram for illustrating a plasma processing apparatus according to some example embodiments.

FIG. 15 is a cross-sectional view taken along a line II-II of FIG. 14.

FIG. 16 is an illustrative diagram for illustrating substrate processing using the plasma processing apparatus of FIG. 14.

FIG. 17 is an illustrative diagram for illustrating a plasma processing apparatus according to some still yet further embodiments.

FIG. 18 is a cross-sectional view taken along III-III of FIG. 17.

FIG. 19 is an illustrative diagram for illustrating substrate processing using the plasma processing apparatus of FIG. 17.

FIG. 20 to FIG. 22 are illustrative diagrams for illustrating a plasma processing apparatus according to some still yet further embodiments.

FIG. 23 and FIG. 24 are illustrative diagrams for illustrating a plasma processing apparatus including a harmonics control module according to some example embodiments.

FIG. 25 to FIG. 27 are illustrative diagrams for illustrating a plasma processing apparatus including a harmonics control module according to some further example embodiments.

FIG. 28 to FIG. 30 are illustrative diagrams for illustrating a harmonics control module according to some example embodiments.

FIG. 31 is an illustrative diagram for illustrating a plasma processing apparatus according to some still yet further embodiments.

### DETAILED DESCRIPTION

For simplicity and clarity of illustration, elements in the drawings are not necessarily drawn to scale. The same reference numbers in different drawings represent the same or similar elements, and as such perform similar functionality. Furthermore, in the following detailed description of various example embodiments, numerous specific details are set forth in order to provide a thorough understanding of various example embodiments. However, it will be understood that various example embodiments may be practiced without these specific details. Examples of various embodiments are illustrated and described further below. It will be understood that the description herein is not intended to limit the claims to the specific embodiments described. On the contrary, it is intended to cover alternatives, modifications, and/or equivalents as may be included in the idea and scope of various example embodiments as defined by the appended claims.

One or more of a shape, a size, a ratio, an angle, a number, etc. disclosed in the drawings for illustrating example embodiments are illustrative, and various example embodiments are not limited thereto. Furthermore, in the following detailed description of various example embodiments, numerous specific details are set forth in order to provide a thorough understanding of various example embodiments. However, it will be understood that various example embodiments may be practiced without these specific details.

The terminology used herein is for the purpose of describing particular example embodiments only and is not intended to limit various example embodiments. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the idea and scope of various example embodiments.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain example embodiments may be implemented differently, a function and/or operation specified in a specific block may occur in a sequence different from that specified in a flowchart. For example, two consecutive blocks may actually be executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated.

The features of the various embodiments of various example embodiments may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the apparatus in use or in operation, in addition to the orientation depicted in the figures. For example, when the apparatus in the drawings may be turned over, elements described as “below” or “beneath” or “under” other elements or features would then be oriented “above” the other elements or features. Thus, the example terms “below” and “under” may encompass both an orientation of above and below. The apparatus may be otherwise oriented, for example, rotated 90 degrees or at other orientations, and the spatially relative descriptors used herein should be interpreted accordingly.

Hereinafter, a plasma processing apparatus according to some example embodiments will be described with reference to the accompanying drawings.

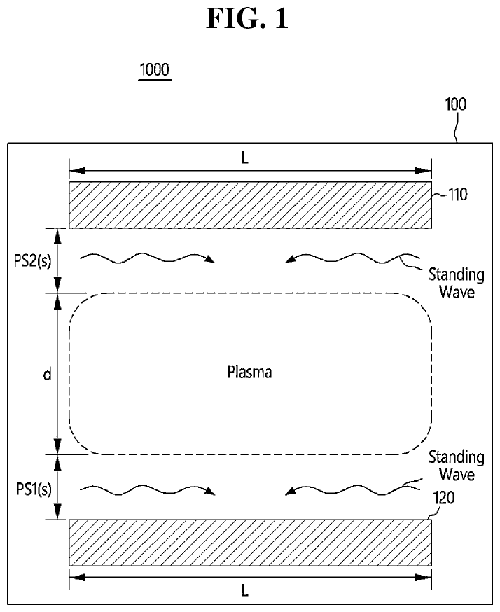

FIG. 1 is a diagram for illustrating a standing wave generated inside a chamber due to harmonics.

Referring to FIG. 1, an upper electrode 110 and a lower electrode 120 may be disposed or arranged in a chamber 100 of a plasma processing apparatus 1000 and may be opposite to each other. In the chamber 100, an operation of processing a substrate (for example, a wafer such as but not limited to a 200 mm wafer or a 300 mm wafer or 450 mm wafer and/or solar substrate and/or a flat-screen display) using plasma may be performed. FIG. 1 shows only the chamber 100, the upper electrode 110, and the lower electrode 120 received in the chamber 100. However, the plasma processing apparatus 1000 may include components for generating the plasma in the chamber 100 and components for processing the substrate using the plasma. In FIG. 1, d denotes a thickness of the plasma and may correspond to a volume of the plasma, PS1 (s) denotes a thickness of a first plasma sheath area PS1, PS2 (s) denotes a thickness of a second plasma sheath area, and L denotes a length of each of the upper electrode 110 and lower electrode 120. In FIG. 1, it is shown that the lengths of the upper electrode 110 and the lower electrode 120 are equal to each other. However, according to various example embodiments, the length of the upper electrode 110 and the length of the lower electrode 120 may be different from each other; e.g., the upper electrode 110 may be shorter than or longer than the lower electrode 120.

In some example embodiments, the upper electrode 110 may be in an electrically isolated or insulated state. Furthermore, high frequency (HF) RF (Radio Frequency) power may be applied to the lower electrode 120 so as to generate the plasma in the chamber 100. For example, the RF power having a frequency of 60 MHz may be applied to the lower electrode 120. In this regard, harmonic components corresponding to integer multiples (for example, 120 MHz, 180 MHz, 240 MHz, etc.) of the fundamental frequency (60 MHz) may be generated in the chamber 100.

In some examples, when the plasma treatment and/or plasma process is performed, the inside of the chamber 100 may be maintained in a vacuum state. In this regard, a wavelength of the harmonics component with high frequency may be reduced to satisfy or at least partly satisfy a standing wave generation condition. Accordingly, the harmonic components performing counter propagation overlap each other, and thus, a standing wave may be generated in the chamber 100. The standing wave may be generated in the first plasma sheath area PS1 between a surface of the lower electrode 120 and the plasma. Furthermore, the standing wave may also be generated in the second plasma sheath area PS2 between the surface of the upper electrode 110 and the plasma.

A standing wave effect may occur wherein a plasma density increases where an intensity of the standing wave is strong while the plasma density decreases where the intensity of the standing wave is weak. In particular, the higher the frequency of the harmonics component, the higher the density of plasma transferred to a central area of the substrate (for example, the wafer), and the lower the density of plasma transferred to an edge portion of the substrate, resulting in non-uniformity in the density distribution of the plasma transferred to the substrate. This may lead to deleterious effects such as improper deposition and/or etching of edge features relative to central features on the substrate.

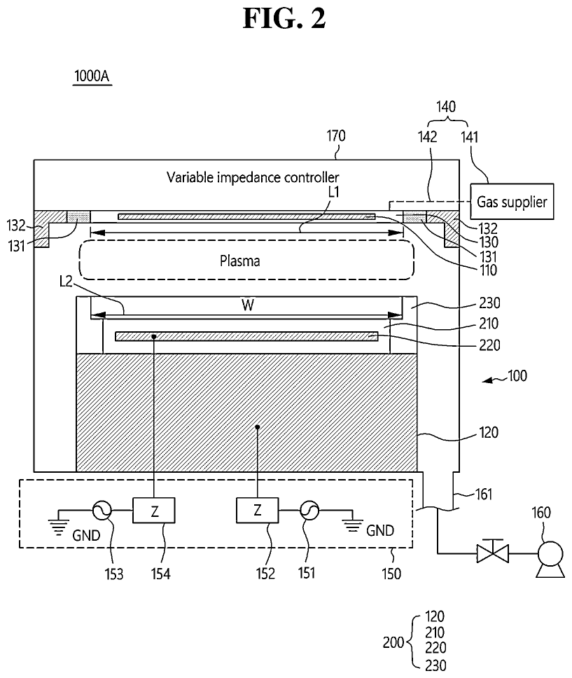

FIG. 2 is an illustrative diagram for illustrating a plasma processing apparatus according to some example embodiments.

Referring to FIG. 2, a plasma processing apparatus 1000A may include a chamber 100, a substrate support module 200, a gas supply module 140, a power supply module 150, and a variable impedance controller 170.

The chamber 100 may provide a space for manufacturing or fabricating a semiconductor device by processing a substrate W using plasma generated therein. For example, the chamber 100 may be an etcher (such as a dry etcher) for etching the surface of the substrate W using plasma generated in a capacitively coupled plasma (CCP) manner. However, the manner in which the plasma processing apparatus 1000A generates the plasma and the substrate processing process performed by the plasma processing apparatus 1000A are not limited thereto. For example, the plasma processing apparatus 1000A may generate the plasma in an inductively coupled plasma (ICP) manner. Furthermore, the plasma processing apparatus 1000A may perform a deposition process of depositing a thin film, for example a chemical vapor deposition (CVD) process, on the surface of the substrate W.

The chamber 100 may have a sealed space of a certain size therein to carry out the process of processing the substrate W. The inner sealed space of the chamber 100 may be in a vacuum or near-vacuum state. Furthermore, the chamber 100 may be formed in various shapes depending on the size of the substrate W. For example, the chamber 100 may have a cylindrical shape corresponding to a disk-shaped substrate W. However, the shape of the chamber 100 shape is not limited thereto. The chamber 100 may include a conductive member made of aluminum and/or steel according to various example embodiments; however, example embodiments are not limited thereto; for example, the chamber 100 may include a ceramic. An electrical ground state may be maintained therein to block or at least partly block noise from an outside while the process is performed therein.

In the chamber 100, a shower head 130 receiving therein an upper electrode 110 and a lower electrode 120 opposite to the upper electrode 110 may be disposed or arranged. As will be described later, the lower electrode 120 may be or include or be included in a component of the substrate support module 200. The shower head 130 in which the upper electrode 110 is received may be surrounded with the insulator 131 in an annular shape. The insulator 131 may be connected to a ground 132. Accordingly, the upper electrode 110 may not be in a ground state but may be in an electrically insulated state. The upper electrode 110 may not be floating. Accordingly, an impedance of the upper electrode 110 may be controlled by the variable impedance controller 170.

The substrate W disposed in the chamber 100 may indicate the substrate W itself or a stack structure including the substrate W and a particular layer and/or film formed on the surface thereof. Furthermore, the surface of the substrate W may indicate an exposed surface of the substrate W itself or an exposed surface of a certain layer or film formed on the substrate W. For example, the substrate W may be or may include a wafer, or may include a wafer and at least one material film disposed on the wafer. The material film may be or include an insulating film and/or a conductive film formed on the wafer via various schemes such as deposition, coating, oxidation, and/or plating. For example, the insulating film may include one or more of an oxide film, a nitride film, or an oxide nitride film, and the conductive film may include a metal film and/or a polysilicon film such as a doped polysilicon film. In one example, the material film having a predetermined pattern may be formed on the wafer.

An outlet 161 connected to a vacuum pump 160 such as a dry pump may be formed at a bottom of the chamber 100. Through the outlet 161, a byproduct produced within the chamber 100 during a process may be discharged to the outside. Alternatively or additionally, the vacuum pump 160 may perform a function of controlling a pressure in the chamber 100.

The substrate support module 200 may include one or more of an electrostatic chuck (ESC) 210, an inner electrode 220, a lower electrode 120, and a focus ring 230. The electrostatic chuck 210 may have an upper surface on which the substrate W is loaded (and may have a diameter greater than or equal to that of the substrate W), and may include a conductive member such as aluminum. The inner electrode 220 may be disposed inside the electrostatic chuck 210. The inner electrode 220 may be connected to an RF power source 153 and may receive RF power therefrom. Accordingly, the substrate W may be electrostatically chucked on the electrostatic chuck 210 under an electrostatic force. In this way, the electrostatic chuck 210 may fix the substrate W to the lower electrode 120 under the electrostatic force, and may fix and maintain the substrate W horizontally. For example, the frequency of the RF power applied to the inner electrode 220 from the RF power source 153 may be 400 kHz. However, various example embodiments are not limited thereto. An impedance matching circuit 154 may be connected to and disposed between the inner electrode 220 and the RF power source 153, and may be configured for matching or at least partly matching an impedance of the inner electrode 220 and an impedance of the RF power source 153 with each other.

The lower electrode 120 may be disposed under the electrostatic chuck 210. The lower electrode 120 may support the electrostatic chuck 210 and the focus ring 230 thereon, and may include a conductive member such as aluminum. However, various example embodiments are not limited thereto. The lower electrode 120 may be connected to an RF power source 151 and may receive the RF power therefrom. For example, the frequency of the RF power applied to the lower electrode 120 from the RF power source 151 may be 60 MHz. However, various example embodiments are not limited thereto. An impedance matching circuit 152 may be connected to and disposed between the lower electrode 120 and the RF power source 151, and may be configured for matching or at least partly matching an impedance of the lower electrode 120 and the impedance of the RF power source 151 with each other. Due to the high frequency RF power applied to the lower electrode 120, an electric field may be generated between the lower electrode 120 and the upper electrode 110.

The focus ring 230 may extend annularly along an edge of, e.g., a circumference of, the electrostatic chuck 210. The focus ring 230 may be made of or may include a dielectric material and/or insulating material to uniformly or more uniformly transmit the electric field onto the substrate W. The focus ring 230 may include, for example, at least one of aluminum oxide (Al₂O₃), aluminum nitride (AlN), silicon (Si), silicon oxide (SiO₂), quartz, silicon carbide (SiC), or yttrium oxide (Y₂O₃).

The gas supply module 140 may include a gas box or gas cabinet or gas supplier 141 and a gas supply pipe 142. The shower head 130 and the gas supplier 141 may be connected to each other via the gas supply pipe 142. The gas supply pipe 142 may be connected to the shower head 130 in which a plurality of gas diffusion holes are formed or defined. The shower head 130 may spray particular gases such as a dynamically determined (or, alternatively, a predetermined) process gas and/or an inert gas such as but not limited to helium and/or nitrogen and/or argon toward the substrate W. The process gas may be or may include an etching gas. However, various example embodiments are not limited thereto. The process gas sprayed into the chamber 100 through the shower head 130 may be converted into plasma under the RF power applied to the lower electrode 120 and may function as an etchant.

The power supply module 150 may include the RF power source 151, the impedance matching circuit 152, the RF power source 153, and the impedance matching circuit 154. The RF power source 151 may generate a first RF signal having a first frequency and may apply the same to the lower electrode 120. The first RF signal may refer to the RF power applied to the lower electrode 120 as described above, and the first frequency may be a fundamental frequency of the RF power. The RF power source 153 may generate a second RF signal having a second frequency and may apply the same to the inner electrode 220. Similarly, the second RF signal may refer to the RF power applied to the inner electrode 220 as described above, and the second frequency may be lower than the first frequency. For example, the first frequency may be 60 MHz and the second frequency may be 400 kHz.

The variable impedance controller 170 may be disposed on the shower head 130 in which the upper electrode 110 is disposed. For example, the variable impedance controller 170 may be disposed in a non-vacuum area on top of the chamber 100. However, example embodiments are not limited thereto, and the variable impedance controller 170 may be disposed in a vacuum area in the chamber 100. The variable impedance controller 170 may control an impedance of a harmonics component generated in an upper area (for example, the second plasma sheath area PS2 in FIG. 1) in the chamber 100. For example, the variable impedance controller 170 may include a combination of a variable inductor and a fixed capacitor, and/or a combination of a variable inductor and a variable capacitor. Accordingly, the variable impedance controller 170 may change an impedance value of the harmonics component to adjust a voltage of the harmonics component to control the harmonics component generated in the chamber 100. Referring to FIG. 2, a length L1 (e.g., a diameter) of the shower head 130 and a length L2 (e.g., a diameter) of the substrate W may be equal to each other. In this case, a plasma density may be controlled while an area on upper surface of the substrate W is not divided into zones, but is set as one zone.

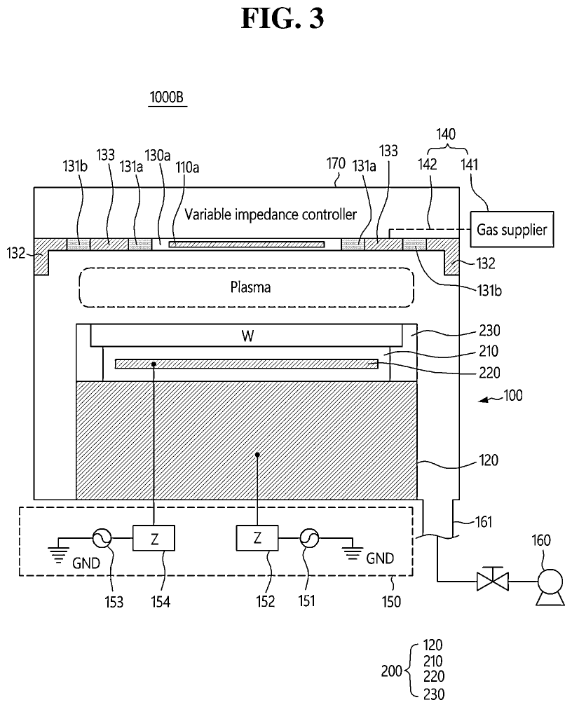

FIG. 3 is an illustrative diagram for illustrating a plasma processing apparatus according to some further example embodiments. Hereinafter, differences thereof from the plasma processing apparatus 1000A as described in FIG. 2 are mainly described.

Referring to FIG. 3, the chamber 100 of the plasma processing apparatus 1000B may include a shower head 130a in which an upper electrode 110a is disposed. The shower head 130a where the upper electrode 110a is disposed may be surrounded with an insulator 131a of an annular shape, and the insulator 131a may be surrounded with a first ground ring 133 of an annular shape. The first ground ring 133 may include a conductive member such as metal and may be in a grounded state. Furthermore, the first ground ring 133 may be surrounded with an insulator 131b extending annularly. The insulator 131b may be connected to a ground 132. Accordingly, the upper electrode 110a may not be in a grounded state but may be in an electrically insulated state. An impedance of the upper electrode 110a may be controlled and/or adjusted by the variable impedance controller 170 connected to the shower head 130a and the first ground ring 133.

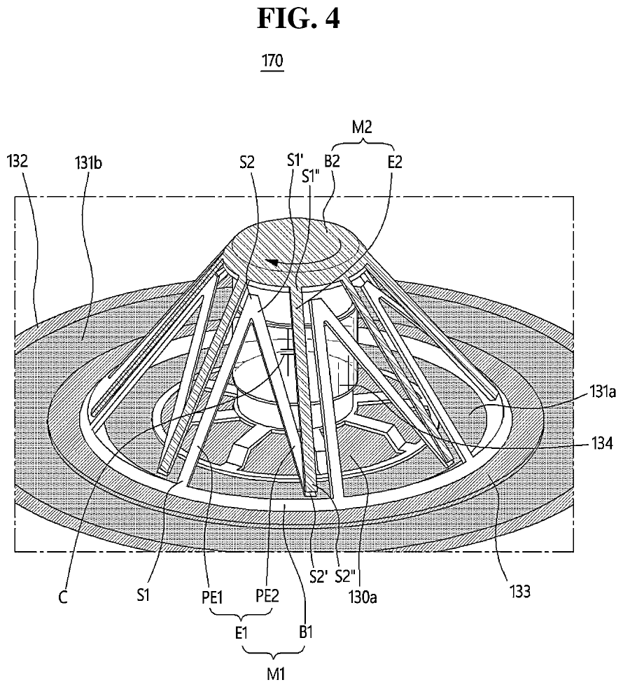

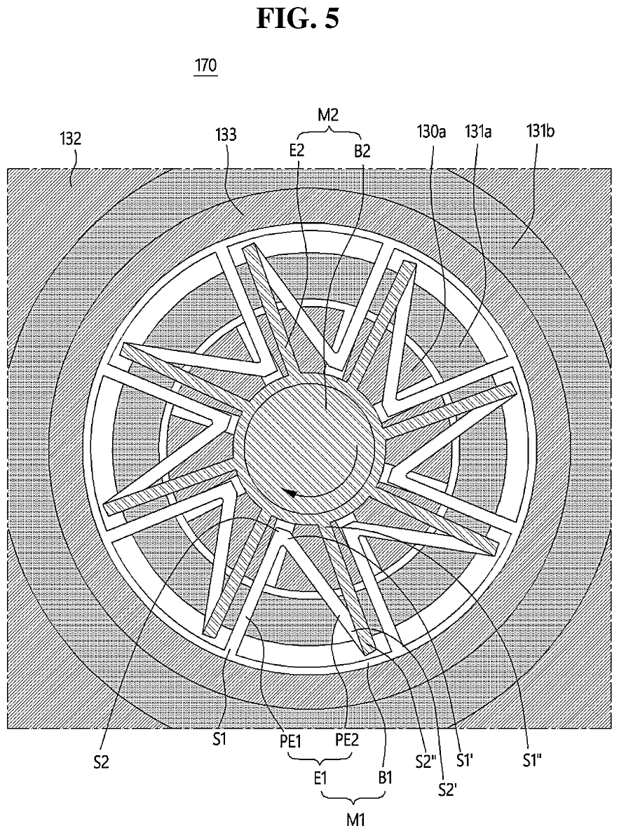

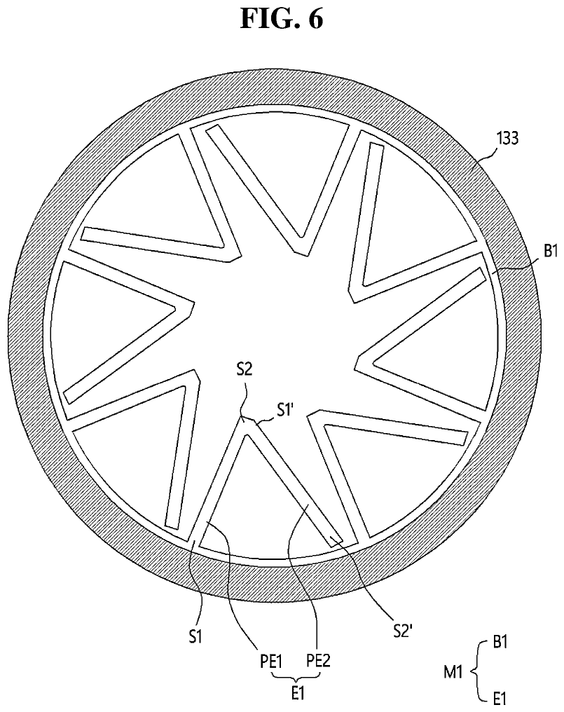

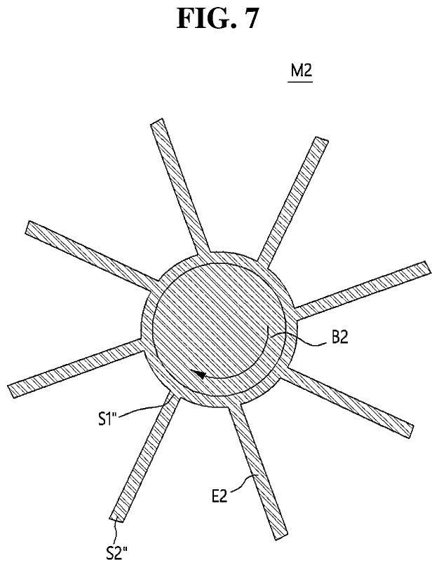

FIG. 4 is an illustrative diagram for illustrating the variable impedance controller of the plasma processing apparatus as shown in FIG. 3. FIG. 5 is an illustrative top view of the variable impedance controller as shown in FIG. 4. FIG. 6 is an illustrative diagram showing a first member of the variable impedance controller in FIG. 5 in a separated state. FIG. 7 is an illustrative diagram showing a second member of the variable impedance controller in FIG. 5 in a separated state. Hereinafter, the variable impedance controller of the plasma processing apparatus according to some example embodiments are described with reference to FIG. 4 to FIG. 7.

The variable impedance controller 170 may include a first member M1 spaced apart from the shower head 130a and extending along an outer edge, e.g., along a circumference of the shower head 130a, and a second member M2 disposed on the first member M1 and configured to rotate. The first member M1 may include a first body B1 electrically insulated from the shower head 130a and surrounding the shower head 130a in an annular shape, and a plurality of first electrodes E1 branching from the first body B1. The first body B1 of the first member M1 may include a conductive member and may be connected to the first ground ring 133 which is in a grounded state or is configured to be in a grounded state. Therefore, the first body B1 may also be in a grounded state. According to various example embodiments, when the variable impedance controller 170 is mounted on the plasma processing apparatus 1000A of FIG. 2, the first body B1 of the first member M1 may be connected to the ground 132.

Although the first body B1 is illustrated as being circular, example embodiments are not limited thereto. For example, the first body B1 may be polygon-shaped, spherical, or elliptically shaped. Furthermore, although the first body B1 is illustrated as defining an imaginary plane upon which the first body sits, example embodiments are not limited thereto. For example, the first body may have a nonplanar lower surface.

The plurality of first electrode E1 may branch from the first body B1 and may be spaced apart from each other, and may include a conductive member. Furthermore, each of the plurality of first electrodes E1 may extend toward the center of the annular first body B1. For example, each of the first electrodes E1 may include a first partial electrode PE1 and a second partial electrode PE2 connected to each other. One side S1 of the first partial electrode PE1 may be connected to the first body B1. The first partial electrode PE1 may extend from the first body B1 to another end S2 of the first partial electrode PE1 upwardly in an inclined manner relative to the plane in which the first body B1 is disposed (for example, an upper surface of the shower head 130a and each of the first ground ring 133). Furthermore, one end S1′ of the second partial electrode PE2 may be connected to the other end S2 of the first partial electrode PE1. The second partial electrode PE2 may extend from one end S1′ of the second partial electrode PE2 downwardly toward the first body B1 in an inclined manner to the plane. For example, referring to FIG. 6, the other end S2′ of the second partial electrode PE2 may be closer to and may face the first body B1.

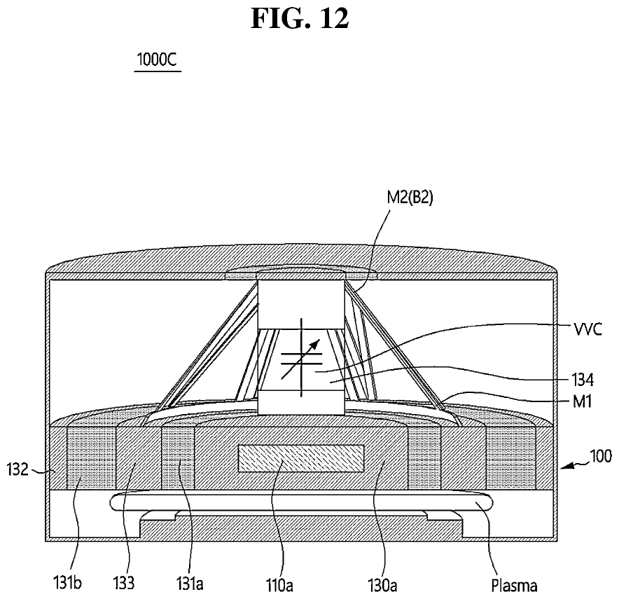

The second member M2 may be disposed on the shower head 130a and may include a conductive member. The second member M2 may be electrically connected to the shower head 130a via a pillar 134. A capacitor C may be disposed inside the pillar 134. Thus, the capacitor C connected to and disposed between the shower head 130a and the second body B2 of the second member M2 may have a fixed capacitance value. However, various example embodiments are not limited thereto. As described later in FIG. 12, the capacitor C connected to and disposed between the shower head 130a and the second body B2 may be or may include a vacuum variable capacitor (VVC).

For example, the second member M2 may include a second body B2 disposed on the shower head 130a and a plurality of second electrodes E2 branching from the second body B2. The plurality of second electrode E2 may be spaced apart from each other while being coupled to the second body B2, and may extend inclinedly downwardly toward the first body B1 of the first member M1. For example, one end S1″ of the second electrode E2 may be connected to the second body B2, and the other end S2″ of the second electrode E2 may be close to and face the first body B1. Depending on various example embodiments, the second electrodes E2 may be arranged so as to be spaced apart from each other by an equal angular spacing. The second member M2 may be connected to a driver (not shown) such as but not limited to a motor so as to be able to rotate while being disposed on the first member M1. Further, when the plasma is generated in the chamber 100 (in FIG. 3), and then a process of treating the substrate W is performed using the plasma, the second member M2 on the first member M1 may be rotated by the driver such that the first electrode E1 and the second electrode E2 may contact each other at one or more contact points/contact areas. Accordingly, a current path along which a current flows from the second body B2 of the second member M2 and then sequentially passes through the second electrode E2 and the first electrode E1 and then reaches the first body B1 of the first member M1 may be established and may be changed.

Accordingly, the variable impedance controller 170 including the first member M1 and the second member M2 may function as a variable inductor. For example, when the path along which the current flows from the second body B2 and then passes through the second electrode E2 and the first electrode E1 and then reaches the first body B1 is short, an inductance of a corresponding current component may be relatively small, and accordingly, an impedance of the corresponding current component may also be relatively small. Conversely, when the path along which the current flows from the second body B2 and then passes through the second electrode E2 and the first electrode E1 and then reaches the first body B1 is long, the inductance of the corresponding current component may be relatively large, and accordingly, the impedance of the corresponding current component may also be relatively large. Thus, rotating the second member M2 of the variable impedance controller 170 of each of the plasma processing apparatus 1000A as shown in FIG. 2 and the plasma processing apparatus 1000B as shown in FIG. 3 according to some example embodiments may allow the impedance of the harmonics component generated in the upper area of the chamber 100 (for example, the second plasma sheath area PS2 of FIG. 1) to be controlled or more precisely controlled.

The first partial electrode PE1 may have the same shape as, or a different shape from, the second partial electrode PE2 and/or the second electrode E2. For example, although the figures illustrate the fits partial electrode PE1, the second partial electrode PE2, and the second electrode E2 as rectangular, example embodiments are not limited thereto. Furthermore, although FIG. 7 illustrates eight second electrodes E2 evenly spaced around the body B2, example embodiments are not limited thereto.

In some example embodiments, while the second member M2 rotates while being disposed on the first member M1, the first electrode E1 and the second electrode E2 may contact each other. Thus, the first electrode E1 and the second electrode E2 may wear out. For this reason, each of the first electrode E1 and the second electrode E2 may not be plated but may be made of a material with low resistance and/or high reliability such as but not limited to silver alloy.

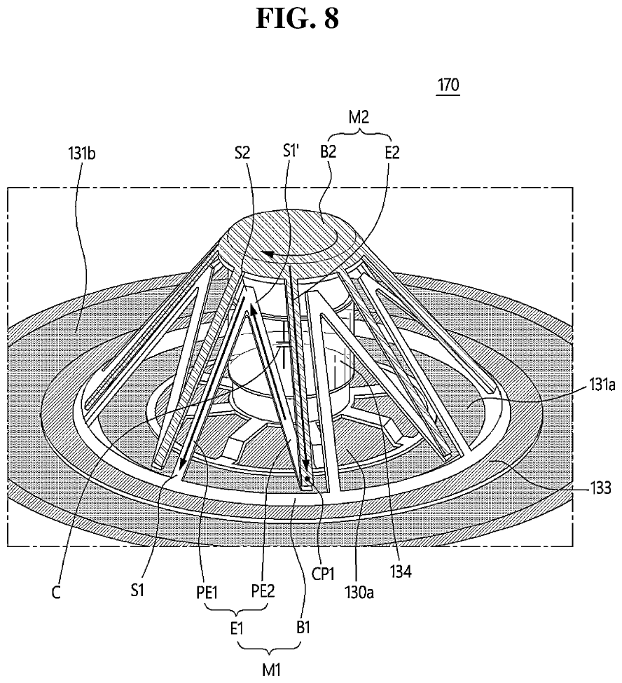

FIG. 8 to FIG. 10 are illustrative diagrams for illustrating how the impedance is changed using the variable impedance controller in FIG. 4.

In FIG. 8 to FIG. 10, an example in which the second member M2 rotates clockwise while being disposed on the fixed first member M1 such that the impedance is changed is described. However, the rotation direction of the second member M2 is not limited thereto. According to various example embodiments, the impedance may be changed while the second member M2 rotates counterclockwise while being disposed on the fixed first member M1.

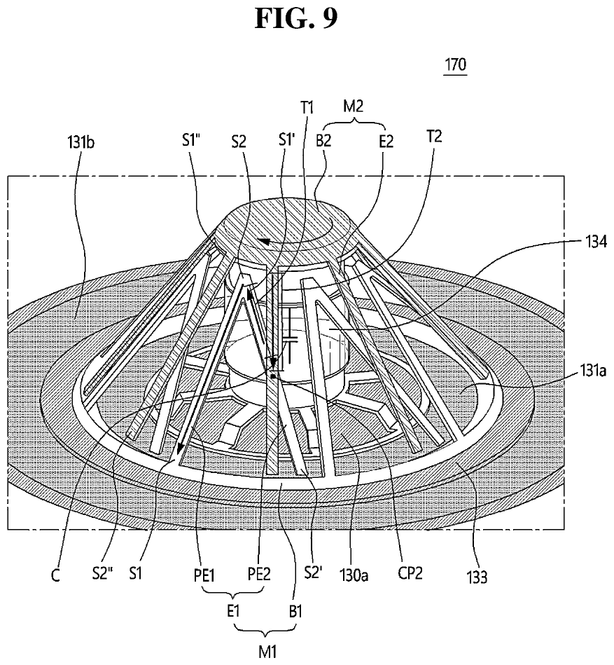

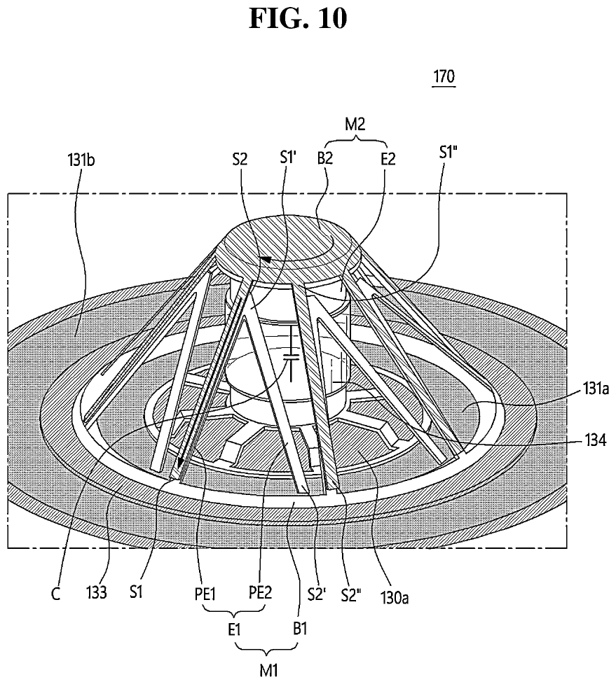

FIG. 8 is a diagram showing a case where the inductance of the current component flowing through the variable impedance controller 170 is the largest. FIG. 9 is a diagram showing a case where the inductance of the current component flowing through the variable impedance controller 170 is smaller than that in FIG. 8. FIG. 10 is a diagram showing a case where the inductance of the current component flowing through the variable impedance controller 170 is the smallest.

First, referring to FIG. 8, a contact point CP1 of the first member M1 and the second member M2 may be positioned at a point where the other end S2′ of the second partial electrode PE2 and the other end S2″ of the second electrode E2 come into contact with each other. In this case, the current component flowing through the variable impedance controller 170 flows from the second body B2 and then passes through an entire length of the second electrode E2, an entire length of the second partial electrode PE2, and an entire length of the first partial electrode PE1 and then reaches the first body B1. Thus, the inductance of the corresponding current component may be the largest.

Next, referring to FIG. 9, FIG. 9 is a diagram showing a state in which the second member M2 is further rotated clockwise from the state in FIG. 8. As the second member M2 rotates, the contact point between the first member M1 and the second member M2 may be changed from the existing contact point CP1 (as shown in FIG. 8) to a new contact point CP2. For example, as shown in FIG. 9, the contact point CP2 may be positioned at a point between one end S1′ and the other end S2′ of the second partial electrode PE2 or between one end S1″ and the other end S2″ of the second electrode E2 at which the second partial electrode PE2 and the second electrode E2 area in contact with each other. In this case, the current component flowing through the variable impedance controller 170 flows from one end S1″ of the second electrode E2 connected to the second body B2 to the contact point CP2, then, from the contact point CP2 to one end S1′ of the second partial electrode PE2, then, from the other end S2 of the first partial electrode PE1 to one end S1 of the first partial electrode PE1, and then, reaches the first body B1. Thus, the current flow path may be shorter than that in FIG. 8. Therefore, the inductance of the corresponding current component may be smaller than that in FIG. 8. Therefore, when the remaining conditions (for example, a size of the capacitor C disposed inside the pillar 134) are the same as those in FIG. 8, the impedance resulting from the first member M1 and the second member M2 may be smaller than that in FIG. 8.

Next, referring to FIG. 10, FIG. 10 is a diagram showing a state in which the second member M2 is further rotated clockwise from the state in FIG. 9. As in FIG. 9, as the second member M2 rotates, the contact point between the first member M1 and the second member M2 may change. For example, as shown in FIG. 10, as the second member M2 rotates, the second electrode E2 and the first partial electrode PE1 may entirely overlap each other. In this case, the current component flowing through the variable impedance controller 170 flows along a straight line from one end S1″ of the second electrode E2 connected to the second body B2 to the first body B1. Thus, the current path through which the current flows may be the shortest, compared to FIG. 8 and FIG. 9. Therefore, when the remaining conditions (for example, a size of the capacitor C disposed inside the pillar 134) are the same as those in FIG. 8 and FIG. 9, the impedance resulting from the first member M1 and the second member M2 may be the smallest.

In this way, as the second member M2 rotates while being disposed on the first member M1, the second electrode E2 contacts the second partial electrode PE2 of the first electrode E1 and then contacts the first partial electrode PE1 thereof. In this regard, a distance along the first electrode E1 from one end S1 of the second partial electrode PE2 to the contact point CP2 is referred to as a first distance T1 (as shown in FIG. 9). A distance along the second electrode E2 from the contact point CP2 to the second body B2 is referred to as a second distance T2 (as shown in FIG. 9). In this case, as the second member M2 rotates, a sum of the first distance T1 and the second distance T2 may change. Accordingly, the inductance value of the current component flowing through the variable impedance controller 170 may be changed, and, therefore, the impedance value due to the first member M1 and the second member M2 may also be changed accordingly.

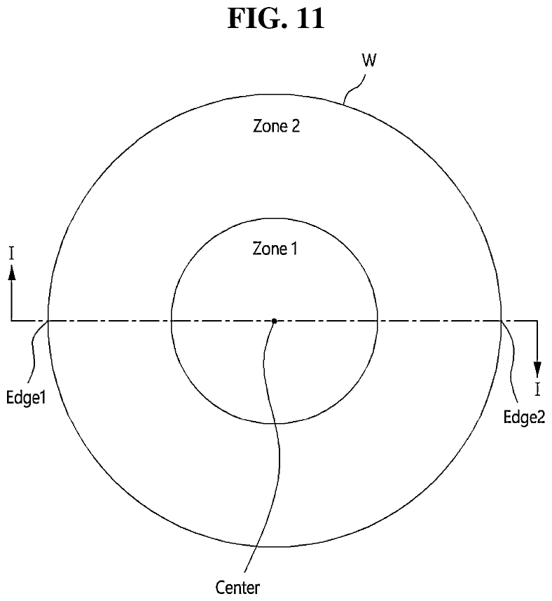

FIG. 11 is an illustrative diagram for illustrating substrate processing and/or treatment using the plasma processing apparatus of FIG. 3.

Referring to FIG. 11, an upper surface of the substrate W may be divided into a first zone 1 and a second zone 2, each defining a concentric circle, based on a distribution of a plasma density. In this regard, the first zone 1 may correspond to an inner area (for example, a center area or center zone) of the substrate W, and the second zone 2 may correspond to an outer area (for example, an edge area or edge zone) of the substrate W. Unlike the plasma processing apparatus 1000A of FIG. 2, in the plasma processing apparatus 1000B of FIG. 3, the first ground ring 133 and the insulator 131b may be further disposed between the shower head 130a receiving therein the upper electrode 110a and the ground 132, such that the area on the substrate W may be divided into two concentric zones, and thus, the plasma density distribution in each of the inner and outer areas of the substrate W may be controlled as needed.

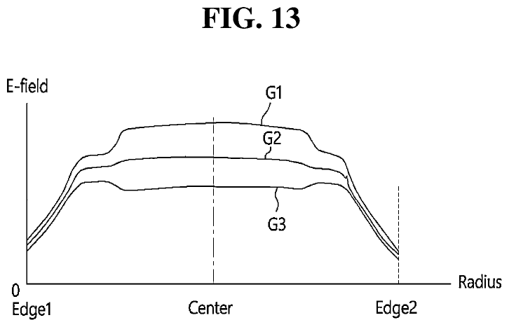

FIG. 12 is an illustrative diagram for illustrating a plasma processing apparatus according to some further example embodiments. FIG. 13 is an illustrative diagram for illustrating a density of plasma generated in a chamber in the plasma processing apparatus of FIG. 12.

First, referring to FIG. 12, unlike FIG. 4, in the plasma processing apparatus 1000C, the vacuum variable capacitor VVC may be disposed inside the pillar 134 connecting the upper electrode 110a and the second member M2 to each other. For example, the shower head 130a and the second body B2 of the second member M2 may be connected to each other while the vacuum variable capacitor VVC is interposed therebetween.

Next, referring to FIG. 13, a horizontal axis of the graph as shown in FIG. 13 represents a position in a radial direction of the substrate W including a central portion Center, a first edge portion Edge 1, a second edge portion Edge 2 in a cross section of the substrate W as cut along I-I of FIG. 11. A vertical axis represents an intensity of an electric field E-field generated under the shower head 130a by the upper electrode 110a in the plasma processing apparatus of FIG. 12. When inductances of G to G3 are equal to each other, G1 is a graph showing a state in which the vacuum variable capacitor VVC (as shown in FIG. 12) is in a short-circuited state, G2 is a graph when a capacitance of the vacuum variable capacitor VVC is 1000 pF, and G3 is a graph showing a state in which the vacuum variable capacitor VVC is open. Thus, a strength of the electric field of the central portion Center of the substrate W at a specific inductance may be controlled and/or adjusted by changing the capacitance value of the vacuum variable capacitor VVC connected to and disposed between the shower head 130a and the second body B2 of the second member M2.

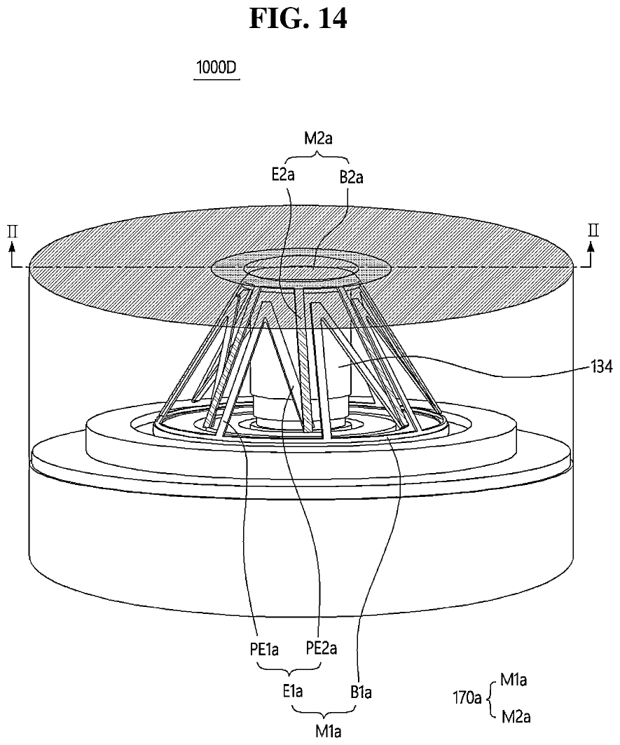

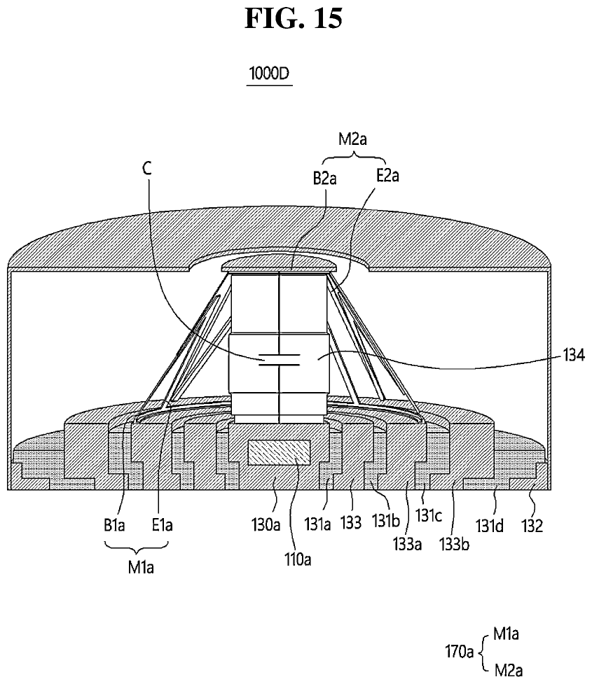

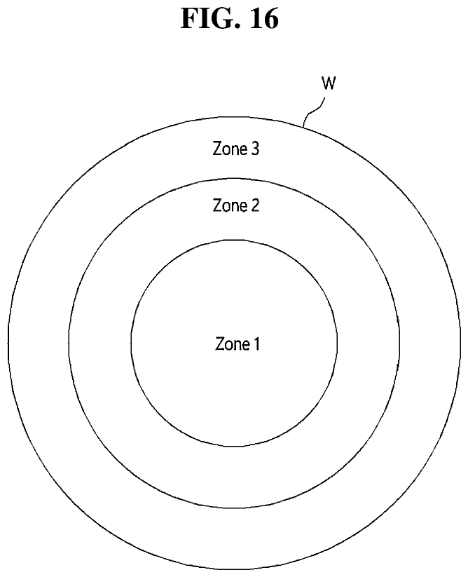

FIG. 14 is an illustrative diagram for illustrating a plasma processing apparatus according to some example embodiments. FIG. 15 is a cross-sectional view taken along a line II-II of FIG. 14. FIG. 16 is an illustrative diagram for illustrating substrate processing using the plasma processing apparatus of FIG. 14. Hereinafter, differences thereof from the previous embodiments will be mainly described.

First, referring to FIG. 14 and FIG. 15, a variable impedance controller 170a of the plasma processing apparatus 1000D may include a first member Mla and a second member M2a. The first member Mla may include a first body Bla and a first electrode Ela, and the second member M2a may include a second body B2a and a second electrode E2a. Furthermore, unlike FIG. 3, the plasma processing apparatus 1000D may further include a second ground ring 133a, an insulator 131c, a third ground ring 133b, and an insulator 131d. The insulator 131d may be connected to the ground 132. Each of the second ground ring 133a and the third ground ring 133b may include a conductive member and may be in a grounded state. Furthermore, each of the insulator 131b, the second ground ring 133a, the insulator 131c, the third ground ring 133b, and the insulator 131d may have an annular shape that surrounds a component inwardly thereof. Accordingly, the upper electrode 110a may not be in a grounded state but may be in an electrically insulated state.

In this regard, unlike as illustrated in FIG. 4, the first body Bla may be connected to the second ground ring 133a rather than the first ground ring 133. Accordingly, as shown in FIG. 16, the upper surface of the substrate W may be divided into a first zone 1, a second zone 2, and a third zone 3, each defining a concentric circle. The distribution of the plasma density transferred to the upper surface of the substrate W may be controlled based on each of the first zone 1, the second zone 2, and the third zone 3. Each zone may have the same radius, or alternatively may have the same area; example embodiments are not limited thereto.

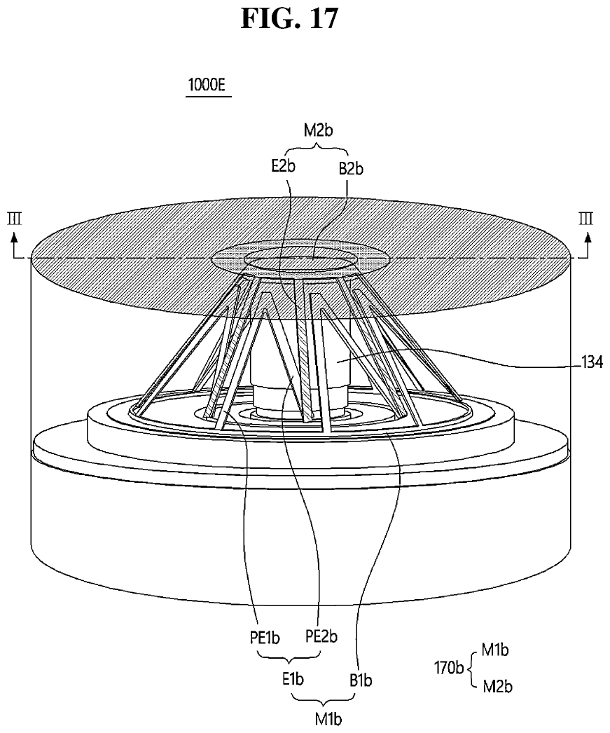

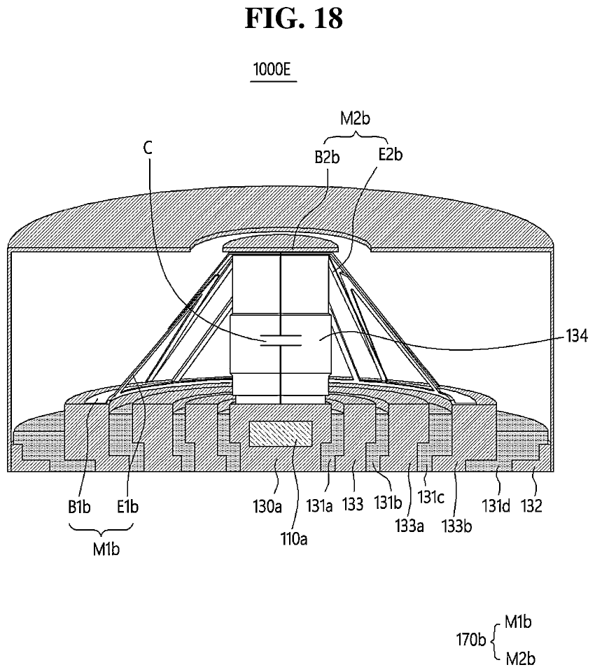

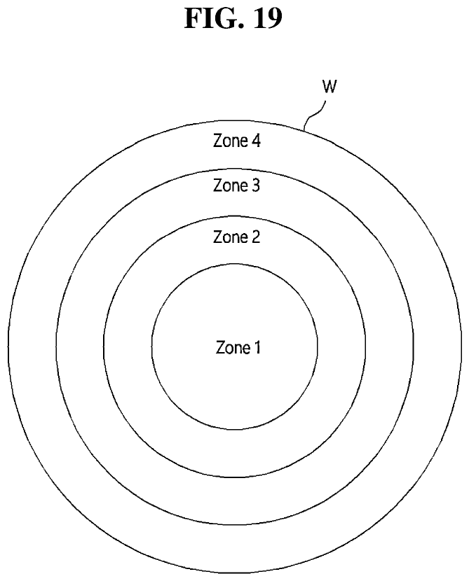

FIG. 17 is an illustrative diagram for illustrating a plasma processing apparatus according to some still yet further embodiments. FIG. 18 is a cross-sectional view taken along III-III of FIG. 17. FIG. 19 is an illustrative diagram for illustrating substrate processing using the plasma processing apparatus of FIG. 17. Hereinafter, differences thereof from the previous embodiments will be mainly described.

First, referring to FIG. 17 and FIG. 18, a variable impedance controller 170b may include a first member M1b and a second member M2b. The first member M1b may include a first body B1b and a first electrode E1b, and the second member M2b may include a second body B2b and a second electrode E2b. In this regard, unlike FIG. 15, the first body B1b may be connected to the third ground ring 133b rather than the second ground ring 133a. Accordingly, as shown in FIG. 19, the upper surface of the substrate W may be divided into a first zone 1, a second zone 2, a third zone 3, and a fourth zone 4, each defining a concentric circle. The distribution of the plasma density transferred to the upper surface of the substrate W may be controlled based on each of the first zone 1, the second zone 2, the third zone 3, and the fourth zone 4.

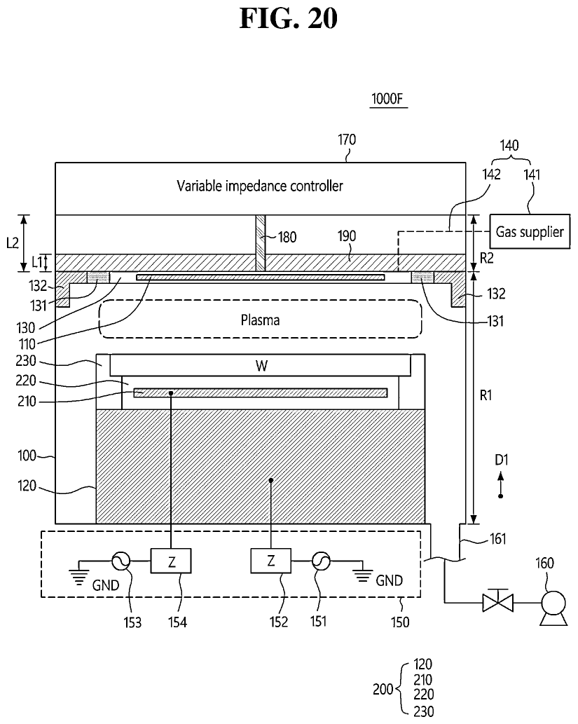

FIG. 20 to FIG. 22 are illustrative diagrams for illustrating a plasma processing apparatus according to some still yet further embodiments. Hereinafter, descriptions duplicate with those of the previous embodiments are omitted, and follows descriptions are based on differences.

First, referring to FIG. 20, unlike FIG. 2, the chamber 100 of a plasma processing apparatus 1000F may be divided into a first area R1 and a second area R2. The second area R2 of the chamber 100 may be disposed between the first area R1 and the variable impedance controller 170. In some example embodiments, the first area R1 of the chamber 100 may be in a vacuum state, and the second area R2 may be in a non-vacuum state. However, example embodiments are not limited thereto, and both the first area R1 and the second area R2 of the chamber 100 may be in a vacuum state. The variable impedance controller 170 of the plasma processing apparatus 1000F may correspond to one of the variable impedance controllers as shown in FIG. 2, FIG. 3, FIG. 12, FIG. 14, and FIG. 17.

In this regard, the upper electrode 110 and the variable impedance controller 170 may be electrically connected to each other via a rod 189 vertically extending through the second area R2. For example, the rod 180 may be connected to the second body (B2 as shown in FIG. 4) of the second member (M2 as shown in FIG. 4). The rod 180 may include a copper (Cu) material and may extend in an elongated manner in a first direction D1 in the second area R2 of the chamber 100.

In some example embodiments, at least a portion of the rod 180 may be surrounded with a ground plate. For example, as shown in FIG. 20, a ground plate 190 having a thickness L1 from a top surface of the first area R1 may be additionally disposed in the second area R2. A lower portion of the rod 180 may be surrounded with the ground plate 190. In this regard, a ratio of a length L1 of the ground plate 190 in the first direction D1 to a length L2 of the second area R2 in the first direction D1 may be ½ or smaller. Alternatively or additionally, according to embodiments, the length L1 of the ground plate 190 in the first direction D1 may be in a range of 30 to 80 mm. Thus, the impedance of the upper electrode 110 may be controlled by adjusting the thickness of the ground plate 190 from the top surface of the first area R1 in the second area R2 of the chamber 100.

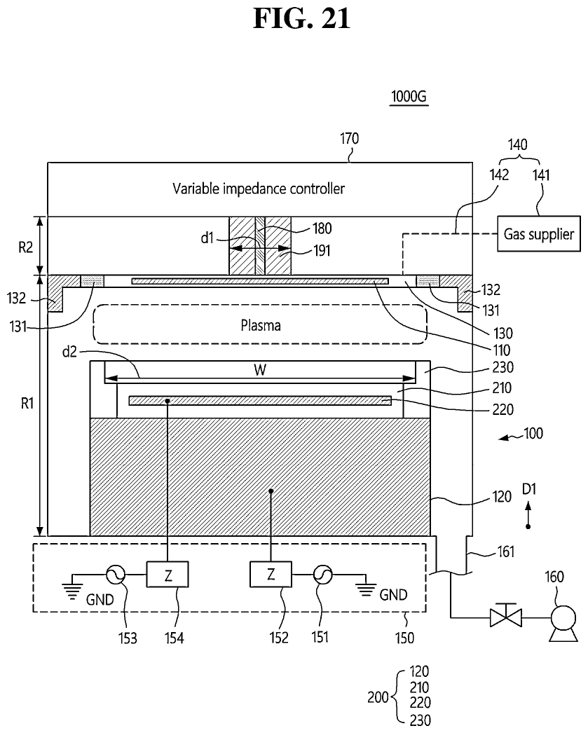

Next, referring to FIG. 21, in a plasma processing apparatus 1000G according to some example embodiments, a cylindrical ground plate 191 extending in an elongate manner in the first direction D1 and surrounding the rod 180 may be additionally disposed in the second area R2. A diameter d1 of the ground plate 191 may be smaller than or equal to ⅓ of a diameter d2 of the disk-type substrate W. In this way, the impedance of the upper electrode 110 may be controlled by adjusting the diameter of the cylindrical ground plate 191 surrounding the rod 180 in the second area R2 of the chamber 100.

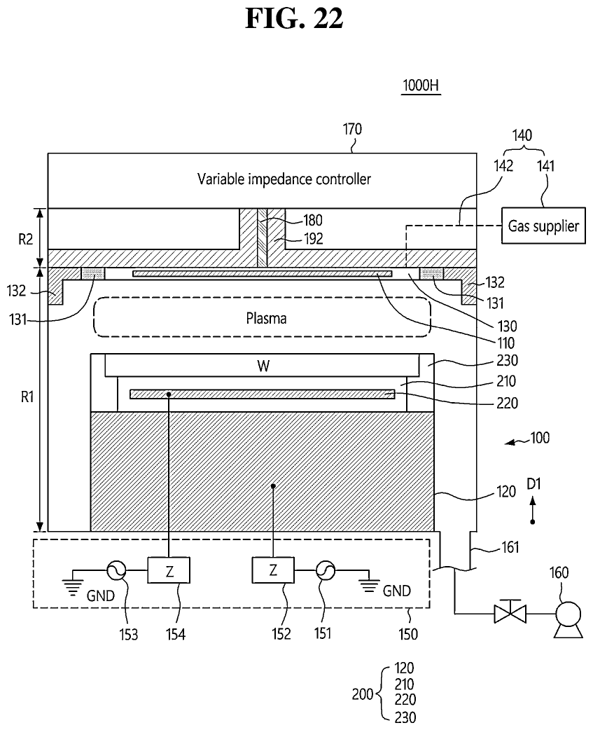

Next, referring to FIG. 22, in a plasma processing apparatus 1000H according to some example embodiments, a top surface of the first area R1 and the rod 180 may be surrounded with a ground plate 192 based on a combination of the ground plate 190 as shown in FIG. 20 and the ground plate 191 as shown in FIG. 21. Accordingly, a length of the ground plate 192 in the first direction D1 and a diameter of the ground plate 192 surrounding a side surface of the rod 180 may be controlled to secure a factor (knob) for controlling the impedance of the upper electrode 110.

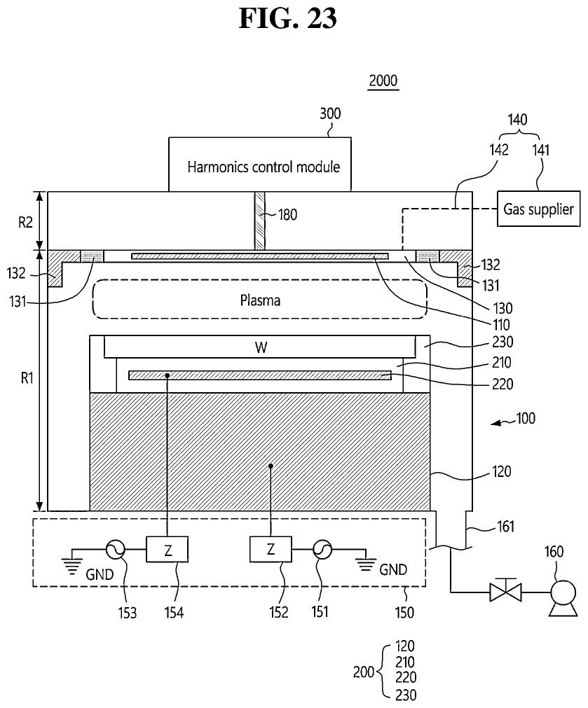

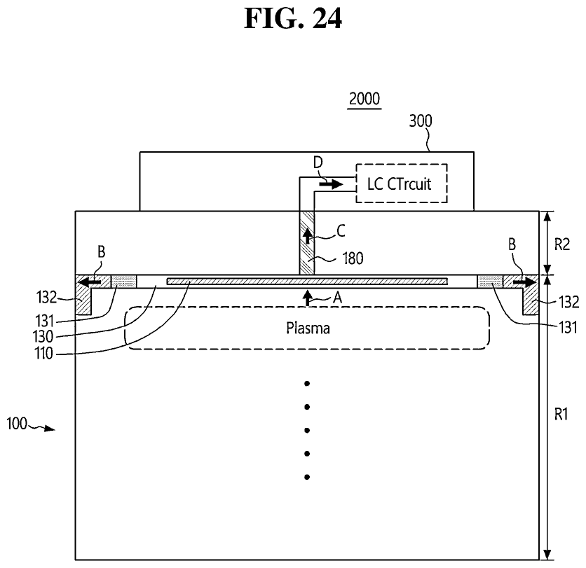

FIG. 23 and FIG. 24 are illustrative diagrams for illustrating a plasma processing apparatus including a harmonics control module according to some example embodiments. Hereinafter, descriptions duplicate with those of the previous embodiments are omitted, and following descriptions are based on differences.

First, referring to FIG. 23, a harmonics control module 300 may be disposed on the second area R2 of the chamber 100 included in the plasma processing apparatus 2000. The harmonics control module 300 may be connected to the upper electrode 110 via the rod 180. In this regard, since the upper electrode 110 is in the electrically insulated state, the impedance of the upper electrode 110 may be controlled using the harmonics control module 300. Therefore, an impedance of a harmonics signals generated between the upper electrode 110 and the plasma in the chamber 100 may be controlled to adjust a voltage of a corresponding harmonics signal component and a density of the plasma generated based on the voltage. Furthermore, the harmonics control module 300 may be disposed on the chamber 100 in a separate manner from the RF power source 151 that applies the RF power to the lower electrode 120 for plasma generation in the chamber 100, and the impedance matching circuit 152 that matches the impedances of the RF power source 151 and the lower electrode 120 with each other. Accordingly, a distance between the harmonics control module 300 and the upper electrode 110 is smaller, such that the impedance of the harmonics signals generated between the upper electrode 110 and the plasma in the chamber 100 may be efficiently controlled. Furthermore, a process in which the harmonics control module 300 controls the harmonics signal generated in the chamber 100 and a process in which the RF power source 151 applies the RF power to the lower electrode 120 may operate independently from each other and thus may not affect each other.

Next, referring to FIG. 24, FIG. 24 is an illustrative diagram for illustrating removal of harmonics generated in the chamber 100 using the plasma processing apparatus 2000 of FIG. 23. In FIG. 24, “A” represents an impedance of an upper structure on the plasma, “B” represents an impedance of the ground 132 surrounding the insulator 131, “C” represents a path impedance of the upper structure, and “D” represents an impedance of the harmonics control module. In this regard, the impedance values “A, B, C, and D” meet a following Equation 1:

$$A = \frac{( C + D ) * B}{C + D + B} \qquad [ Equation 1 ]$$

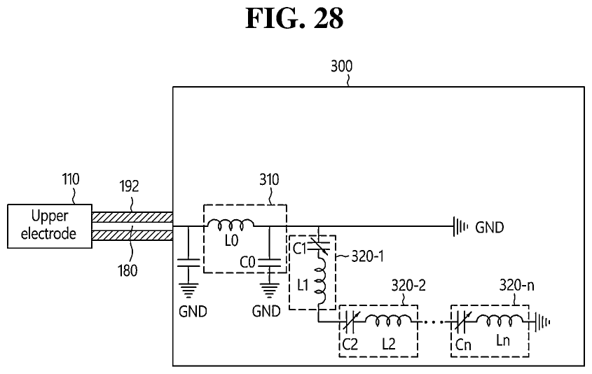

Accordingly, the impedance B may be increased, and the impedance C may be lowered to reduce an amount of current flowing to B and increase an amount of current flowing to C and D, such that the harmonics component generated in the upper area (for example, an area between the upper electrode 110 and the plasma) of the inner area of the chamber 100 may be removed out of the chamber 100. In some example embodiments, the harmonics control module 300 may be embodied as an LC circuit in order to remove the harmonics component generated in the chamber 100. A configuration of the harmonics control module 300 will be described later with reference to FIG. 28 to FIG. 30.

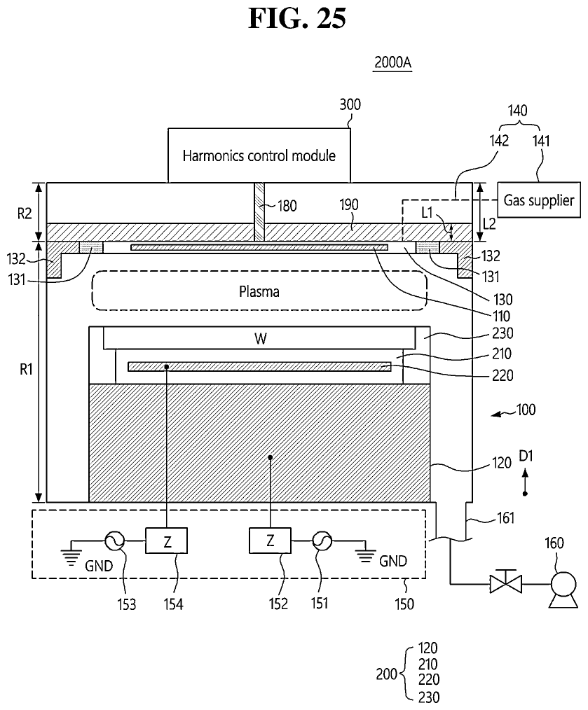

FIG. 25 to FIG. 27 are illustrative diagrams for illustrating a plasma processing apparatus including a harmonics control module according to some further example embodiments.

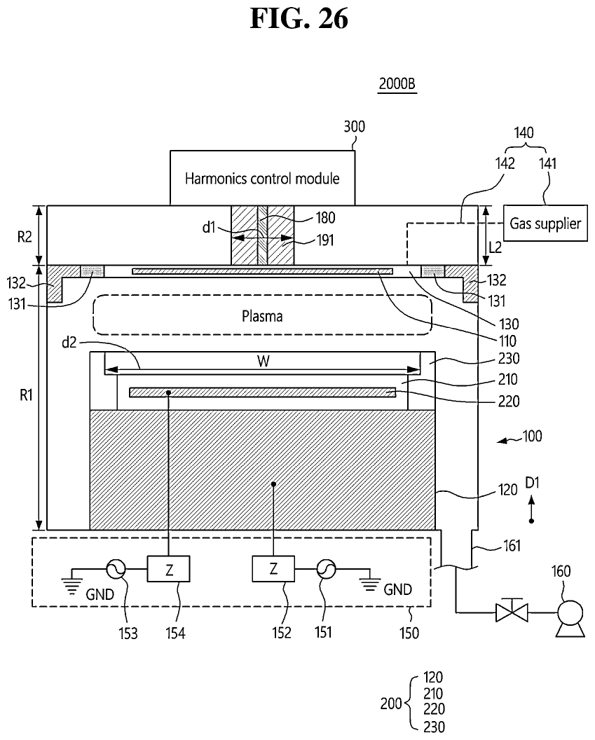

Referring to FIG. 25 to FIG. 27, at least a portion of the rod 180 may be surrounded with the ground plate. For example, referring to FIG. 25, the ground plate 190 having the thickness L1 from the top surface of the first area R1 in the first direction D1 may be further disposed in the second area R2 of the chamber 100 included in the plasma processing apparatus 2000A. The lower portion of the rod 180 may be surrounded with the ground plate 190. Furthermore, referring to FIG. 26, the cylindrical ground plate 191 extending in the first direction D1 and surrounding the rod 180 may be additionally disposed in the second area R2. According to various example embodiments, the diameter d1 of the ground plate 191 may be smaller than or equal to ⅓ of the diameter d2 of the disk-shaped substrate W.

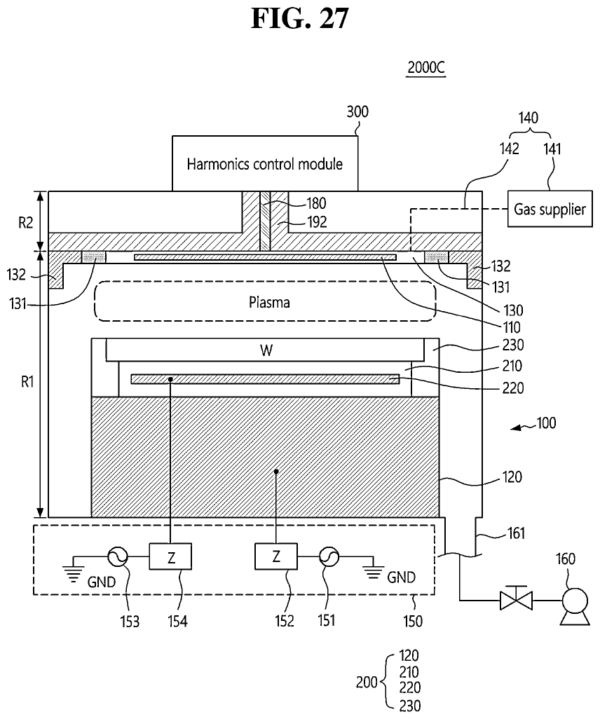

Furthermore, referring to FIG. 27, the top surface of the first area R1 and the rod 180 may be surrounded with the ground plate 192 based on a combination of the ground plate 190 as shown in FIG. 25 and the ground plate 191 as shown in FIG. 26. The descriptions of the ground plates 190, 191, and 192 as shown in FIG. 25 to FIG. 27 are the same as the descriptions of the ground plates 190, 191, and 192 as shown in FIG. 20 to FIG. 22, respectively, and thus are omitted below.

FIG. 28 to FIG. 30 are illustrative diagrams for illustrating a harmonics control module according to some example embodiments.

First, referring to FIG. 28, the harmonics control module 300 may be connected to the upper electrode 110 via the rod 180, and at least a portion of the rod 180 may be surrounded with the ground plate 192. The harmonics control module 300 may include a filter 310 and a first harmonics control circuit to an n^{th} harmonics control circuit 320-1, 320-2, . . . , 320-n, where n is an integer greater than or equal to 2. The filter 310 may be embodied as an LC filter including an inductor L0 and a capacitor C0. The filter 310 may filter the first RF signal having the first frequency generated from the RF power source (151 as shown in FIG. 27) from among signals transmitted via the upper electrode 110 and the rod 180. Accordingly, only harmonics signals having high frequencies equal to integer multiples of the first frequency may be controlled in a later stage.

The first harmonics control circuit 320-1 may control a first harmonic signal having a frequency equal to two times of the first frequency. The first harmonics control circuit 320-1 may include an inductor L1 having a fixed inductance value and a variable capacitor C1. The second harmonics control circuit 320-2 may control a second harmonic signal having a frequency equal to three times of the first frequency. The second harmonics control circuit 320-2 may include an inductor L2 having a fixed inductance value and a variable capacitor C2. The second harmonics control circuit 320-2 may be connected in series to the first harmonics control circuit 320-1. Similarly, the n^{th} harmonics control circuit 320-n having a fixed-type inductor Ln and a variable capacitor Cn may control an n^{th} harmonic signal having a frequency equal to (n+1) times of the first frequency. In this way, each of the first to n^{th} harmonics control circuits 320-1, 320-2, . . . , 320-n connected in series with each other may remove (or control) a corresponding harmonic signal. Hereinafter, differences from the previous embodiments will be mainly described.

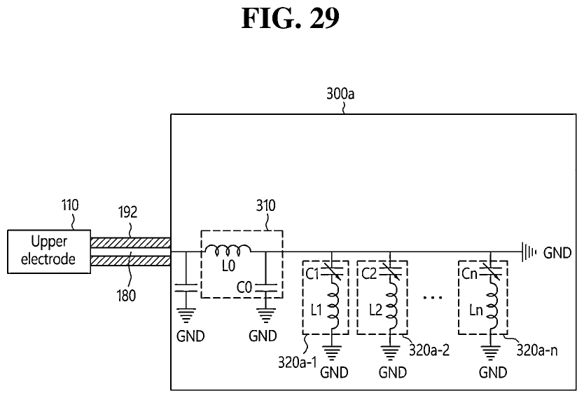

Next, referring to FIG. 29, unlike FIG. 28, first to n^{th} harmonics control circuits 320a-1, 320a-2, . . . , 320a-n included in a harmonics control module 300a are connected in parallel to each other.

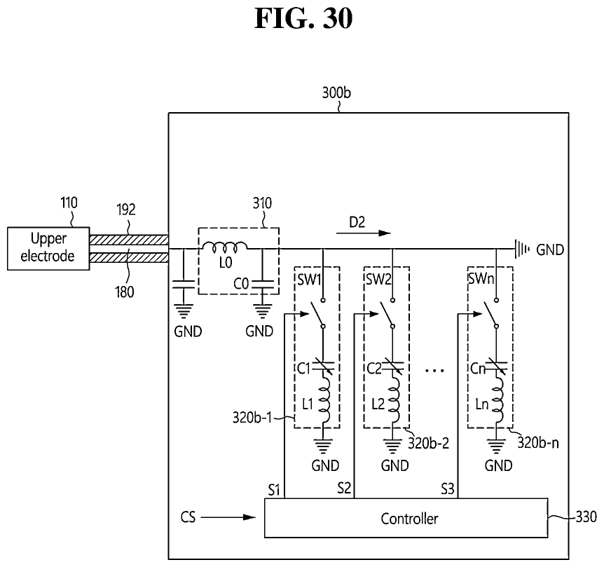

Next, referring to FIG. 30, a harmonics control module 300b may further include a controller 330 and first to n^{th} switches SW1 to SWn. The first to n^{th} switches SW1 to SWn may be included in the first to n^{th} harmonics control circuits 320b-1, 320b-2, . . . , 320b-n, respectively. The controller 330 may generate first to n^{th} switch signals S1 to Sn based on a control signal CS and a total impedance set to reduce the harmonics component. The total impedance set to reduce the harmonics component may be expressed as a combination of at least some of the first to n^{th} switch signals S1 to Sn activated in response to the control signal CS. For example, when the total impedance is C1+C2, only the first switch signal S1 and the second switch signal S2 may be activated in synchronization with the control signal CS, while the remaining switch signals S3 to Sn may be always deactivated regardless of the control signal CS. In this case, the total impedance of C1+C2 may be periodically added to a path through which the signal flows in a second direction D2 in response to the control signal CS, thereby providing a leakage path of the harmonics component. In this way, the harmonics control module 300b may remove (or control) each of the harmonics signals using the controller 330 and each of the first to n^{th} harmonics control circuits 320b-1, 320b-2, . . . , 320b-n connected in parallel to each other.

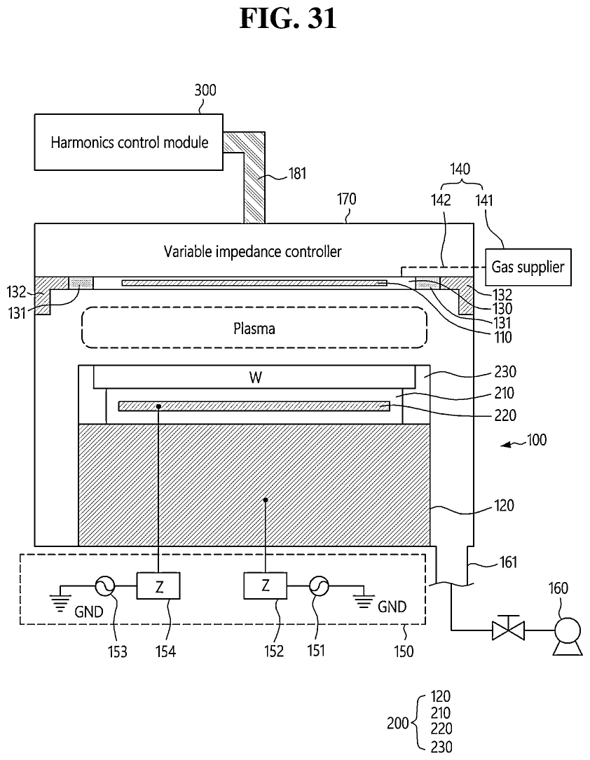

FIG. 31 is an illustrative diagram for illustrating a plasma processing apparatus according to some still yet further embodiments. Hereinafter, descriptions duplicate with those of the previous embodiments are omitted, and following descriptions are based on differences.

Referring to FIG. 31, a plasma processing apparatus 3000 may include the variable impedance controller 170 disposed on the shower head 130 receiving therein the upper electrode 110 and the harmonics control module 300 connected to the variable impedance controller 170 through the rod 181. Accordingly, the impedance and the voltage of the harmonics component generated in the chamber of the plasma processing apparatus 3000 may be controlled and/or adjusted using the variable impedance controller 170, and the harmonics component may be removed (or controlled) using the harmonics control module 300.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Although various example embodiments of various example embodiments have been described with reference to the accompanying drawings, example embodiments are not limited to the above and may be implemented in various different forms. Those of ordinary skill in the technical field to which example embodiments belongs will be able to understand that example embodiments may be implemented in other specific forms without changing the technical idea or essential characteristics of variously described example embodiments. Therefore, it should be understood that the embodiments as described above are not restrictive but illustrative in all respects. Furthermore, example embodiments are not necessarily mutually exclusive with one another. For example, some example embodiments may include one or more features described with reference to one or more figures, and may also include one or more other features described with reference to one or more other figures.

What is claimed is:

1. A plasma processing apparatus comprising:
a shower head configured to receive an electrode therein; and
a variable impedance controller on the shower head,
wherein the variable impedance controller includes
a first member spaced apart from the shower head and arranged along a circumference of the shower head, and
a second member on the first member and configured to rotate,
wherein the variable impedance controller is configured to control an impedance by changing the impedance resulting from the first member and the second member as at least one contact point between the first member and the second member is changed according to rotation of the second member.

2. The plasma processing apparatus of claim 1, wherein the first member includes:
a first body electrically insulated from the shower head and surrounding the shower head;
a plurality of first electrodes branching from the first body and spaced apart from each other, wherein each of the plurality of first electrodes extends toward a center of the first body.

3. The plasma processing apparatus of claim 2, wherein
the first body has a planar shape,
one end of each of the first electrodes is connected to the first body, and
each of the first electrodes extends from the one end to another end thereof upwardly and in an inclined manner relative to a plane along which the first body is arranged.

4. The plasma processing apparatus of claim 2, wherein
the first body has a planar shape,
each of the first electrodes includes a first partial electrode and a second partial electrode connected to each other,
one end of the first partial electrode is connected to the first body,
the first partial electrode extends from the one end of the first partial electrode to another end of the first partial electrode upwardly and in an inclined manner relative to a plane along which the first body is arranged,
one end of the second partial electrode is connected to the other end of the first partial electrode, and
the second partial electrode extends from the one end thereof toward the first body downwardly and in an inclined manner.

5. The plasma processing apparatus of claim 4, wherein the second member includes:
a second body on the shower head; and
a plurality of second electrodes branching from the second body and spaced apart from each other, wherein each of the plurality of second electrodes extends toward the first body of the first member.

6. The plasma processing apparatus of claim 5, wherein the variable impedance controller is configured to operate such that as the second member rotates, the second electrode contacts the second partial electrode of a corresponding first electrode and then contacts the first partial electrode thereof.

7. The plasma processing apparatus of claim 5, wherein
a distance along the first electrode from one end of the second partial electrode to the contact point is defined as a first distance,
a distance along the second electrode from the contact point to the second body is defined as a second distance, and
the variable impedance controller is configured to operate such that as the second member rotates, a sum of the first distance and the second distance changes.

8. The plasma processing apparatus of claim 5, further comprising:
a capacitor connected to and arranged between the shower head and the second body.

9. The plasma processing apparatus of claim 8, wherein the capacitor includes a vacuum variable capacitor.

10. A plasma processing apparatus comprising:
a shower head configured to receive an electrode therein; and
a variable impedance controller around the shower head and on the shower head,
wherein the variable impedance controller includes,
a first member including
a first body spaced apart from the shower head and surrounding the shower head, and
a plurality of first electrodes branching from the first body and spaced apart from each other, wherein each of the plurality of first electrodes extends toward a center of the first body, and
the variable impedance controller further includes a second member including,
a second body on the shower head, and
a plurality of second electrodes branching from the second body and spaced apart from each other, wherein each of the plurality of second electrodes extends toward the first body of the first member, and
the second member is on the first member and is configured to rotate on the first member.

11. The plasma processing apparatus of claim 10, wherein the variable impedance controller is configured to operate such that as the second member rotates, at least one contact point between the first member and the second member is changed.

12. The plasma processing apparatus of claim 10, wherein an insulator is between the shower head and the first body.

13. A plasma processing apparatus comprising:
a chamber including a first area configured to have a shower head that is configured to have an upper electrode arranged therein and a lower electrode arranged opposite to the upper electrode;
a substrate support module in the chamber and configured to support a substrate thereupon;
a gas supply module configured to supply a process gas into the chamber;
a power supply module configured to generate a first radio frequency (RF) signal having a first frequency and apply the first RF signal to the lower electrode;
a variable impedance controller on the chamber and configured to control an impedance of harmonics generated in the chamber,
wherein the variable impedance controller includes,
a first member spaced apart from the shower head and arranged along an outer edge of the shower head, and
a second member on the first member and configured to rotate,
wherein as the second member rotates, at least one contact point between the first member and the second member is changed, such that an impedance resulting from the first member and the second member is changed.

14. The plasma processing apparatus of claim 13, wherein
the chamber further includes a second area defined between the first area and the variable impedance controller, and
the upper electrode and the variable impedance controller are electrically connected to each other via a rod, wherein the rod is in the second area and extends in an elongate manner in a first direction.

15. The plasma processing apparatus of claim 14, wherein
the second area extends from an upper surface of the upper electrode by a first length in the first direction, and
a first ground plate surrounding at least a portion of the rod is received in the second area.

16. The plasma processing apparatus of claim 15, wherein a ratio of the first length to a length in the first direction of the second area is ½ or smaller.

17. The plasma processing apparatus of claim 16, wherein the plasma processing apparatus is configured to operate such that the first area is in a vacuum state, and the second area is in a non-vacuum state.

18. The plasma processing apparatus of claim 14, wherein
the second area extends in the first direction, and
a second ground plate surrounding the rod is received in the second area.

19. The plasma processing apparatus of claim 13, wherein the power supply module is configured to generate a second RF signal having a second frequency lower than the first frequency, and
the power supply module is configured to apply the second RF signal to the substrate support module.

20. The plasma processing apparatus of claim 13, wherein the
power supply module includes an RF power source and an impedance matching circuit, and
the impedance matching circuit is between the RF power source and the lower electrode.
